(19) United States
(12) Patent Application Publication
(10) Pub. No.: US 2022/0184876 A1
(43) Pub. Date: Jun. 16, 2022

(54) PLANARIZATION APPARATUS, PLANARIZATION METHOD, AND ARTICLE MANUFACTURING METHOD

(71) Applicant: CANON KABUSHIKI KAISHA, Tokyo (JP)

(72) Inventors: Yuki Morita, Kanagawa (JP); Hiroyuki Kondo, Tochigi (JP)

(21) Appl. No.: 17/542,214

(22) Filed: Dec. 3, 2021

(30) Foreign Application Priority Data
Dec. 10, 2020 (JP) 2020-205114

(51) Int. Cl. B29C 59/02; B29C 35/08

(52) U.S. Cl. CPC B29C 59/022; B29C 2035/0827; B29C 35/0805; B29C 59/026

(57) ABSTRACT

A planarization apparatus that planarizes a composition on a substrate using a mold includes a substrate holding unit configured to hold the substrate, a mold holding unit configured to hold the mold, a drive unit configured to drive the substrate holding unit and the mold holding unit, a pressing member configured to press a part of the mold which is in contact with the substrate with a composition interposed therebetween to separate the substrate from the mold, and a control unit configured to control a position of the pressing member to a predetermined position.

### BACKGROUND OF THE INVENTION

### Field of the Invention

The present disclosure relates to a planarization apparatus, a planarization method, and an article manufacturing method.

### Description of the Related Art

With a growing demand for the miniaturization of semiconductor devices, attention has been drawn to, in addition to conventional photolithography techniques, a microfabrication technique of molding an uncured composition on a substrate using a mold and curing the molded composition, thereby forming a pattern of the composition on the substrate. Such a technique is called an imprint technique, and can form a fine pattern on a substrate in the order of a few nanometers.

In recent years a technique of performing a planarization process on a substrate using the imprint technique has been proposed (Japanese Unexamined Patent Application Publication (Translation of PCT Application) No. 2011-529626). There is a type of a planarization processing apparatus using the imprint technique which includes two processing units. First, in one (hereinafter referred to as “processing unit 1”) of the processing units, an optical imprint material (hereinafter referred to as “curable composition”) curable by ultraviolet light is applied onto the entire surface of a substrate (wafer). Next, the substrate is conveyed to the other processing unit (hereinafter referred to as “processing unit 2”), and subsequently, in the processing unit 2, the curable composition applied onto the substrate is molded by being brought into contact with (pressed onto) a template having a flat surface. The curable composition is then cured by irradiation with (exposed to) ultraviolet light in the state where the curable composition is in contact with the template having the flat surface. After the curing, the template is separated (released) from the cured film. Through the above-described processing steps, the cured film is formed on the substrate in a state where the flat surface of the template is transferred to the substrate. The planarization process for the substrate can be performed in such a manner.

It is known that, in such a planarization apparatus, the composition on the substrate and the mold are brought into contact with each other by a large contact area and then separated from each other, and thus a mold releasing force is large as compared with an imprint apparatus. If the mold releasing force is large, there is a possibility that the release operation itself cannot be normally performed, or the composition on the substrate cannot be normally planarized because the mold is released forcibly from the composition. Therefore, a technique has been discussed that provides a release starting point by pushing up the mold in contact with the cured product on the substrate from the substrate side, using a push pin (a pressing member) or the like, in order to stably perform the mold releasing. However, there is a possibility that the push pin cannot reliably push up the mold because of misalignment or the like.

### SUMMARY OF THE INVENTION

According to as aspect of the present disclosure, a planarization apparatus that planarizes a composition on a substrate using a mold includes a substrate holding unit configured to hold the substrate, a mold holding unit configured to hold the mold, a drive unit configured to drive the substrate holding unit and the mold holding unit, a pressing member configured to press a part of the mold which is in contact with the substrate with a composition interposed therebetween to separate the substrate from the mold, and a control unit configured to control a position of the pressing member to a predetermined position.

Further features of the present disclosure will become apparent from the following description of exemplary embodiments with reference to the attached drawings.

### BRIEF DESCRIPTION OF THE DRAWINGS

FIGS. 1A and 1B are schematic diagrams illustrating a configuration of a planarization apparatus.

FIGS. 2A, 2B, and 2C are diagrams illustrating a planarization process in the planarization apparatus.

FIG. 3 is a schematic diagram illustrating a configuration of a substrate holding unit according to each exemplary embodiment.

FIG. 4 is a schematic diagram illustrating a configuration of a template holding unit according to each exemplary embodiment.

FIGS. 5A, 5B, and 5C are diagrams illustrating a release process using a push pin.

FIG. 6 is a flowchart illustrating a planarization process according to a first exemplary embodiment.

FIGS. 7A, 7B, and 7C are diagrams illustrating a release process according to the first exemplary embodiment.

FIG. 8 is a flowchart illustrating a planarization process according to a second exemplary embodiment.

FIGS. 9A, 9B, and 9C are diagrams illustrating a release process according to the second exemplary embodiment.

FIG. 10 is a flowchart illustrating a planarization process according to a third exemplary embodiment.

FIGS. 11A, 11B, and 11C are diagrams illustrating a release process according to the third exemplary embodiment.

### DESCRIPTION OF THE EMBODIMENTS

Exemplary embodiments of the present disclosure will be described below with reference to the attached drawings. In each of the drawings, identical members are assigned the same reference numbers and the repeated description thereof will be omitted.

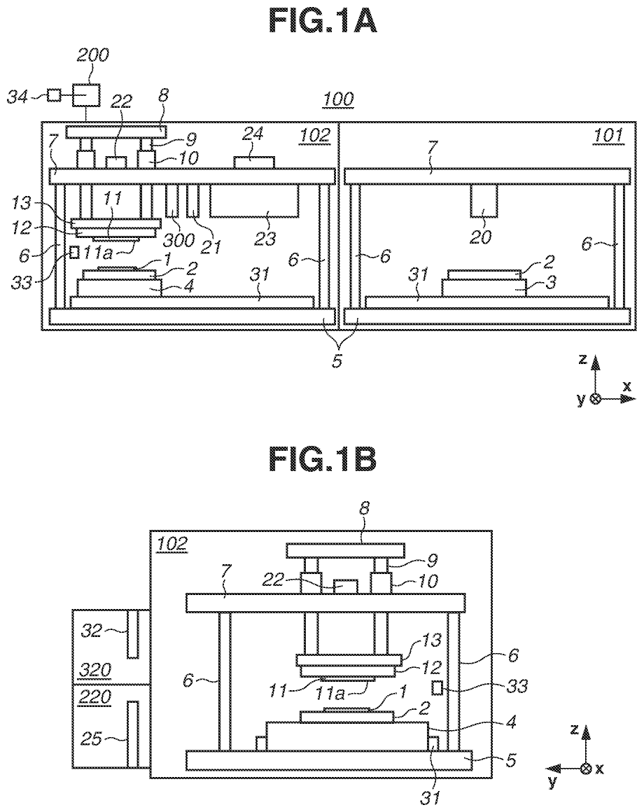

FIGS. 1A and 1B are schematic diagrams illustrating a configuration of a planarization apparatus 100. FIG. 1A is a diagram illustrating the planarization apparatus 100 as viewed along a Y-axis, and FIG. 1B is a diagram illustrating the planarization apparatus 100 as viewed along an X-axis. The planarization apparatus 100 is configured to perform a molding process of molding a curable composition on a substrate 1. Specifically, the planarization apparatus 100 includes a first processing unit 101, a second processing unit 102, a substrate conveyance processing unit 220, and a template conveyance processing unit 320.

The first processing unit 101 performs an application step of applying a curable composition onto the substrate 1. The second processing unit 102 performs a contact step of bringing the curable composition on the substrate 1 and a template 11 into contact with each other, a curing step of curing the curable composition in a state of being in contact with the template 11, and a release step of separating the curable composition from the template 11 after the curing. In a planarized-layer forming process, the above-described steps are sequentially performed. In the exemplary embodiments of the present disclosure, the example in which the first processing unit 101 and the second processing unit 102 are used is described, but a single processing unit may be used to perform the steps.

In the present specification and the attached drawings, directions are expressed in an XYZ coordinate system in which a direction parallel to a surface of the substrate 1 is an XY plane. A direction parallel to the X-axis, a direction parallel to the Y-axis, and a direction parallel to a Z-axis in the XYZ coordinate system are an X-axis direction, a Y-axis direction, and a Z-axis direction, respectively. A rotation around the X-axis, a rotation around the Y-axis, and a rotation around the Z-axis are θX, θY, and θZ, respectively. Control or driving related to the X-axis, control or driving related to the Y-axis, and control or driving related to the Z-axis indicate control or driving related to the X-axis direction, control or driving related to the Y-axis direction, and control or driving related to the Z-axis direction, respectively. Further, control or driving related to the θX-axis, control or driving related to the θY-axis, and control or driving related to the θZ-axis indicate control or driving related to a rotation around an axis parallel to the X-axis, control or driving related to a rotation around an axis parallel to the Y-axis, and control or driving related to a rotation around an axis parallel to the Z-axis, respectively. Furthermore, a position is information that can be identified based on coordinates on the X-axis, the Y-axis, and the Z-axis, and an orientation is information that can be identified by values of the θX-axis, the θY-axis, and the θZ-axis. Alignment indicates control of the position and/or the orientation. The alignment can include control of the position and/or the orientation of at least one of the substrate 1 and the template 11. The alignment can further include control for correcting or changing the shape of at least one of the substrate 1 and the template 11.

For the curable composition, a curable composition (may be referred to as uncured resin) to be cured by application of energy for curing is used. As the energy for curing, an electromagnetic wave, heat, or the like is used. The electromagnetic wave is, for example, infrared light, visible light, or ultraviolet light of which the wavelength is selected from the range of 10 nm to 1 mm.

Curable compositions are cured by irradiation with light or by heating. A photocurable composition to be cured by light contains at least a polymerizable compound and a photopolymerization initiator, and may contain a non-polymerizable compound or a solvent as appropriate. The non-polymerizable compound is at least one selected from a group including a sensitizer, a hydrogen donor, an internal mold release agent, a surfactant, an antioxidant, and a polymer component. The curable composition is applied in the form of a film onto the substrate by a spin coater or a slit coater. Alternatively, the curable composition may be applied onto the substrate by a liquid jet head, in the form of droplets or in the form of an island or film formed of connected droplets. The viscosity (viscosity at 25° C.) of the curable composition is, for example, 1 mPa·s or more and 100 mPa·s or less.

The planarization apparatus 100 can form a planarized film (a planarized layer) from the curable composition on the substrate 1, using the template (may also be referred to as a mold or a super straight) 11 having a flat surface 11a. In this case, the curable composition is cured in a state where the flat surface 11a is in contact with the curable composition. Such a planarization apparatus forms a planarized film on a plurality of shot regions that are formed on the substrate by an imprinting apparatus, in a single planarization process. And it is also desirable that the template and the substrate be about the same in size. A template partially having a pattern can be also used as the template 11, and although the planarization apparatus will be described as an example, each of the exemplary embodiments of the present disclosure is also applicable to an imprint apparatus.

For example, a silicon wafer is a representative base material for the substrate 1, but the substrate 1 is not limited thereto. The substrate 1 can be freely selected from known substrates that are used for semiconductor devices and made of materials such as aluminum, titanium-tungsten alloy, aluminum-silicon alloy, aluminum-copper-silicon alloy, silicon oxide, and silicon nitride. A substrate having an adhesion layer formed by a surface treatment, such as silane coupling treatment, silazane treatment, or organic thin film formation, to improve adhesion to the curable composition may be used for the substrate 1. The substrate 1 typically has the shape of a circle with a diameter of 300 mm, but is not limited thereto.

In a case where light is used as the energy for curing, it may be desirable to form the template 11 using a material through which the curing light can pass. The template 11 is made of, for example, at least one of glass, quartz, light transmissive resin such as polymethyl methacrylate (PMMA) or polycarbonate resin, a transparent metal deposition film, a flexible film of polydimethylsiloxane, a photo-cured film, and a metallic film.

The template 11 desirably has the shape of a circle with a diameter of 300 mm that is substantially the same as the size of the substrate 1, but may be larger than the substrate 1 to some extent, and is not limited thereto. Furthermore, the thickness of the template 11 can be 0.25 mm or more and 2 mm or less in this example, but is not limited thereto if the template 11 has rigidity to follow the surface shape when placed on the substrate 1.

Next, a structure of each of the first processing unit 101 and the second processing unit 102 will be described with reference to FIGS. 1A and 1B. The description will be provided below using an example in which UV light is used as the energy for curing. In this case, for example, monomer such as acrylate or methacrylate can be adopted for the curable composition.

The first processing unit 101 and the second processing unit 102 each have a substrate holding unit 2 (a substrate chuck), a stage drive unit 31, a base surface plate 5, props 6, and a top plate 7, as illustrated in FIGS. 1A and 1B.

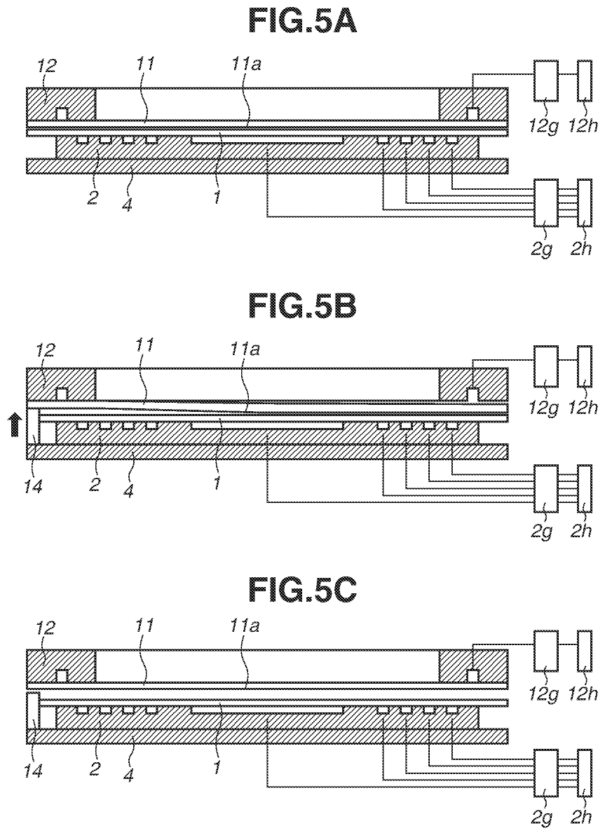

The first processing unit 101 further includes a substrate stage 3 and a dispenser 20 (a droplet supply unit). The second processing unit 102 further includes a substrate stage 4, a guide bar plate 8, a guide bar 9, a head drive unit 10, a template holding unit 12, and a head 13. The second processing unit 102 further includes an off-axis alignment (OA) scope 21, an alignment scope 22, an exposure unit 23 (a curing unit), a light source 24, a cleaning unit 33, and a detection unit 300. In the second processing unit 102, the substrate stage 4 includes a push pin 14 (a pressing member) illustrated in FIGS. 5A to 5C to be described below. The planarization apparatus 100 further includes a substrate conveyance unit 25, an input unit 34, and a control unit 200.

The substrate holding unit 2 includes a chuck such as a vacuum chuck or an electrostatic chuck, and holds the substrate 1 using the chuck. The substrate stage 3 and the substrate stage 4 are each supported by the base surface plate 5, and each hold the substrate holding unit 2. Further, the substrate stage 3 and the substrate stage 4 are each driven in the X-axis direction and the Y-axis direction to position the substrate 1 held by the substrate holding unit 2 at a predetermined position. The stage drive units 31 each include a linear motor and an air cylinder, and drive the substrate stage 3 or the substrate stage 4 at least in the X-axis direction and the Y-axis direction. The stage drive units 31 each may have a function of driving the substrate stage 3 or the substrate stage 4 in two or more axial directions (e.g., six axial directions). The stage drive units 31 each further include a rotation mechanism, and drive the substrate holding unit 2 or the substrate stage 3 or the substrate stage 4 about the θZ-axis.

The template holding unit 12 includes a chuck such as a vacuum chuck or an electrostatic chuck, and holds the template 11 using the chuck. The head 13 holds the template holding unit 12 (a mold holding unit). The head drive unit 10 drives the template holding unit 12 by driving the head 13, thereby driving the template 11. The head drive unit 10 may be configured to drive the template 11 along a plurality of axes.

The props 6 supporting the top plate 7 is on each of the base surface plates 5. The guide bar 9 in the second processing unit 102 passes through the top plate 7, one end of the guide bar 9 is fixed to the guide bar plate 8, and the other end is fixed to the head 13. The head drive unit 10 drives the head 13 in the Z-axis direction by driving the guide bar 9. This makes it possible to bring the template 11 held by the template holding unit 12 into contact with the curable composition on the substrate 1, and release the template 11 from the curable composition on the substrate 1. The head drive unit 10 may include a mechanism of driving the head 13 in other axes other than the Z-axis. Alternatively, the head drive unit 10 can include a mechanism of driving the head 13 along a plurality of axes (e.g., three axes of the θX-axis, the θY-axis, and the Z-axis, or six axes of the X-axis, the Y-axis, the Z-axis, the θX-axis, the θY-axis, and the θZ-axis).

The substrate conveyance processing unit 220 includes the substrate conveyance unit 25 including a conveyance hand, and a substrate storage shelf (not illustrated) for temporarily storing a substrate carried in from outside the planarization apparatus 100 and a substrate processed by each of the first processing unit 101 and the second processing unit 102. The substrate conveyance unit 25 can convey the substrate between the substrate storage shelf and each of the first processing unit 101 and the second processing unit 102. The template conveyance processing unit 320 includes a template storage shelf (not illustrated) for temporarily storing a template carried in from outside the planarization apparatus 100 by a template conveyance unit 32 including a conveyance hand. In place of such a storage shelf, a conveyable storage unit may be disposed.

The dispenser 20 (a supply unit) in the first processing unit 101 places or supplies an uncured (liquid) curable composition onto the substrate 1. The dispenser 20 can include a discharge port (a nozzle) for discharging the curable composition. For example, the dispenser 20 supplies a micro-volume (e.g., 1 picoliter) droplet of the curable composition onto the substrate 1 by a method such as a piezo jet method or a micro solenoid method. The number of the discharge ports in the dispenser 20 is not limited to a specific number, and may be one or may be more than one. As an example, the dispenser 20 has 100 or more discharge ports. Such a plurality of discharge ports is arranged, for example, in one line or a plurality of lines.

The push pin 14 of the substrate stage 4 has a role as an assisting function in releasing the template 11 from the curable composition on the substrate 1. Specifically, the push pin 14 is caused to protrude toward the template 11 from an opening region of a notch portion such as a notch or an orientation flat of the substrate 1, when the template 11 is released from the curable composition on the substrate 1. When the push pin 14 is caused to protrude and press the template 11 in a state where the template 11 is held by the substrate holding unit 2, a force is applied in a direction in which the template 11 separates from the substrate 1. In this manner, the push pin 14 can assist in the release step of releasing the template 11.

The alignment scope 22 includes an optical system and an image pickup system to observe a reference mark on the substrate stage 4 and an alignment mark on the template 11. The alignment scope 22 can be used to perform alignment by measuring the relative positions of the reference mark on the substrate stage 4 and the alignment mark on the template 11 and correcting the misalignment thereof

The detection unit 300 can detect the position of the notch portion such as the notch or orientation flat of the substrate 1 held by the substrate holding unit 2. Specifically, the detection unit 300 can include an optical sensor capable of detecting the external form profile of the substrate 1, a small camera capable of directly observing the shape of the substrate 1, and the like. The detection unit 300 can also be used as a unit for detecting the position of the push pin 14 on the substrate stage 4. The alignment to be described below can be performed by using the position information about the push pin 14 and the notch portion of the substrate 1 obtained by the detection unit 300.

The exposure unit 23 is provided with a window portion through which the energy (e.g., light such as the UV light) for curing supplied from the light source 24 is to pass. The exposure unit 23 can cure the curable composition with the light emitted in a state where the substrate stage 4 holding the substrate 1 in contact with the template 11 with the curable composition interposed therebetween faces the exposure unit 23 (in a curing position).

The OA scope 21 is supported by the top plate 7. The OA scope 21 can be used for a global alignment process of detecting alignment marks in a plurality of shot regions of the substrate 1 and determining the position of each of the plurality of shot regions. The relative alignment between the template 11 and the substrate 1 can be performed by determining the positional relationship between the template 11 and the substrate stage 4 using the alignment scope 22 and determining the positional relationship between the substrate stage 4 and the substrate 1 using the OA scope 21.

The cleaning unit 33 can clean the template 11 in a state where the template 11 is held by the template holding unit 12. For example, the cleaning unit 33 removes the curable composition remaining on the template 11, in particular, on the flat surface 11a thereof, when the template 11 is released from the cured curable composition on the substrate 1. For example, the cleaning unit 33 may wipe the curable composition adhering to the template 11, or may remove the curable composition adhering to the template 11 using UV irradiation, wet cleaning, or plasma cleaning.

The control unit 200 includes a processing unit and a storage unit such as a memory, and controls the entire planarization apparatus 100. The control unit 200 is configured of, for example, a programmable logic device (PLD) such as a field programmable gate array (FPGA), an application specific integrated circuit (ASIC), a general-purpose or dedicated computer incorporating a program, or the combination of all or some of these. The control unit 200 functions as a processing unit that performs a planarization process by controlling each unit of the planarization apparatus 100.

The planarization process is an example of the molding process of molding the curable composition on the substrate 1, and is a process of forming a film having a planarized surface using the cured product of the curable composition. To be more specific, the planarization process is a process of planarizing the curable composition by bringing the flat surface 11a of the template 11 into contact with the curable composition on the substrate 1 to follow the surface shape of the substrate 1. The planarization process is typically performed in a unit of lot, i.e., for each of a plurality of substrates included in the same lot.

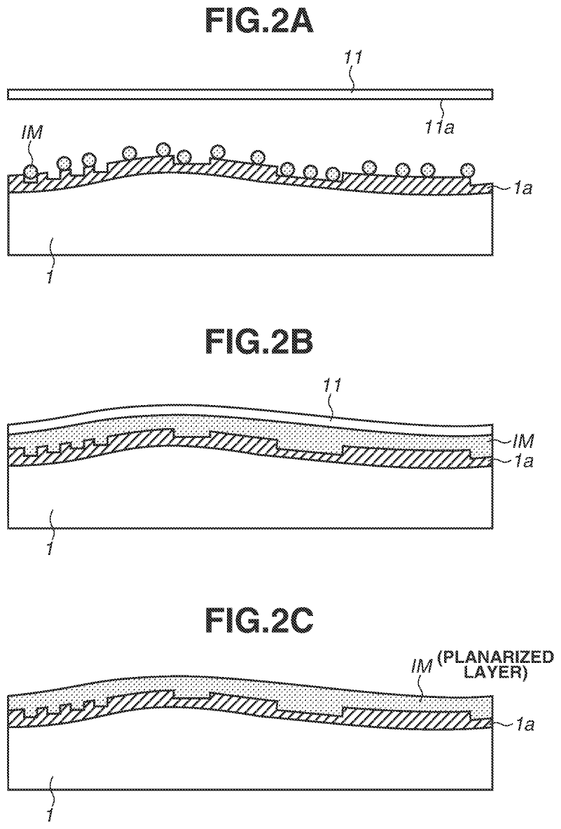

Next, the outline of an overall flow of the planarization process according to the present disclosure will be described with reference to FIGS. 2A to 2C. Here, a description will be given of a process of planarizing a composition applied in the form of a droplet on the entire surface of a substrate and bringing the composition and a mold into contact with each other, but the composition may be planarized by bringing the composition applied in a partial region of the substrate and the mold into contact with each other.

As illustrated in FIG. 2A, a curable composition IM is supplied or placed onto the substrate 1 having a base pattern 1a by the dispenser 20 of the first processing unit 101. FIG. 2A illustrates a state where the curable composition IM is supplied onto the substrate 1 before the template 11 (the flat surface 11a) is brought into contact with the curable composition IM. The substrate 1 is then conveyed from the first processing unit 101 to the second processing unit 102 by the substrate conveyance unit 25.

Next, as illustrated in FIG. 2B, the distance between the substrate 1 and the template 11 is adjusted by the head drive unit 10 so that the curable composition IM on the substrate 1 and the template 11 (the flat surface 11 a thereof) come in contact with each other (the contact step). FIG. 2B illustrates a state where the template 11 is released from the template holding unit 12, the flat surface 11a of the template 11 is completely in contact with the curable composition IM on the substrate 1, and the flat surface 11a of the template 11 follows the surface shape of the substrate 1.

Subsequently, the substrate stage 4 is driven to the position of the exposure unit 23 in the state illustrated in FIG. 2B. Then, the light source 24 applies the energy for curing to the curable composition IM on the substrate 1 via the template 11, thereby curing the curable composition IM (the curing step).

Next, the substrate stage 4 is driven to the position of the head drive unit 10, and the distance between the substrate 1 and the template 11 is adjusted by the head drive unit 10 so that the template 11 separates from the curable composition IM cured on the substrate 1. Thereafter, in a state where the template holding unit 12 is holding the template 11, the substrate 1 and the template 11 are moved away from each other in the Z-axis direction, so that the template 11 is separated from the curable composition IM on the substrate 1 (the release step). The push pin 14 assists in this step.

As a result, a layer (a planarized layer) made of the curable composition IM and having a uniform thickness can be formed in the entire area of the substrate 1. FIG. 2C illustrates a state where the planarized layer consisting of the cured product of the curable composition IM is formed on the substrate 1.

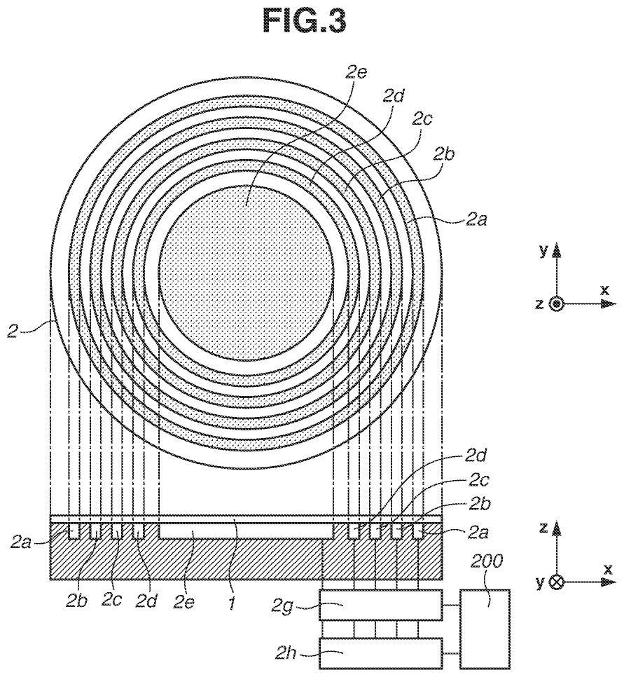

Next, the release step of separating the template 11 from the curable composition IM cured on the substrate 1 using the push pin 14 in the above-described planarization process will be described in detail with reference to FIG. 3 to FIG. 5C.

FIG. 3 is a diagram illustrating a state where the substrate 1 is held by the substrate holding unit 2. As illustrated in FIG. 3, the substrate holding unit 2 includes vacuum lines 2a to 2e for holding the substrate 1 by vacuum suction. There is disposed a pressure detector 2g for detecting the vacuum state of each of the vacuum lines 2a to 2e, i.e., the value of pressure inside each of the vacuum lines 2a to 2e, when the substrate 1 is held by vacuum suction. Further, there is disposed a pressure adjustment unit 2h for adjusting the vacuum pressure of each of the vacuum lines 2a to 2e. The control unit 200 performs this pressure adjustment.

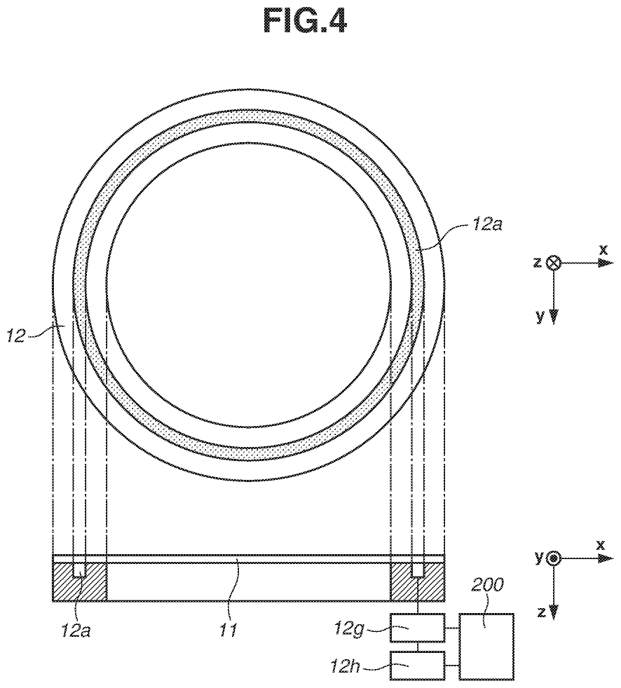

FIG. 4 is a diagram illustrating a state where the template 11 is held by the template holding unit 12. As illustrated in FIG. 4, the template holding unit 12 includes a vacuum line 12a for holding the template 11 by vacuum suction. There is disposed a pressure detector 12g for detecting the vacuum state of the vacuum line 12a, i.e., the value of pressure inside the vacuum line 12a, when the template 11 is held by vacuum suction. Further, a pressure adjustment unit 12h for adjusting the vacuum pressure of the vacuum line 12a is disposed. The control unit 200 performs this pressure adjustment.

FIGS. 5A to 5C are diagrams illustrating a flow of the release process using the push pin 14. FIG. 5A illustrates a state where the flat surface 11a of the template 11 is in contact with the substrate 1 while following the surface shape of the substrate 1 before the release processing is started, and the curable composition on the substrate 1 is cured. In this state, the control unit 200 controls the pressure adjustment unit 2h and the pressure adjustment unit 12h to obtain a predetermined vacuum pressure desirable for the release.

Next, FIG. 5B illustrates operation during the release. The template 11 is raised by the head drive unit 10 and separated from the curable composition cured on the substrate 1. In this operation, the push pin 14 of the substrate stage 4 is caused to protrude from the opening of the notch portion of the substrate 1 and pressed against a part of the template 11, thereby assisting the release. Specifically, a starting point for releasing is generated when the push pin 14 is pressed against the part of the template 11, thereby facilitating the release.

FIG. 5C illustrates a state after the release. This is a state where the template 11 is completely separated from the curable composition cured on the substrate 1.

In a case where the substrate 1 and the template 11 are about the same size, it is desirable to make the position of the push pin 14 and the position of the notch portion of the substrate 1 held by the substrate holding unit 2 match each other in order to push up the template 11 from the substrate side. If the shape of the template 11 is larger than that of the substrate 1 to some extent, it is not necessary to make the position of the notch portion of the substrate 1 and the position of the push pin 14 match each other. However, it is necessary to position the push pin 14 at a predetermined position for enabling the push pin 14 to push up the template 11 without touching the substrate 1, when the template 11 is raised from the substrate 1 side. Nevertheless, there is a possibility that the push pin 14 cannot be held at such a desirable position because of misalignment, and in such a state, the push pin 14 cannot assist the release.

To solve the issue, as will be described in detail in the following exemplary embodiment, the position of the push pin 14 is adjusted, so that the template 11 can be stably released from the curable composition on the substrate, using the push pin 14.

In a first exemplary embodiment, a description will be given of a case where the push pin 14 integrally formed in the substrate stage 4 is adjusted in a state where the template 11 and the substrate 1 are held by the template holding unit 12. In the present exemplary embodiment, a case where the position of the push pin 14 matches the notch portion of the substrate 1 will be described as an example.

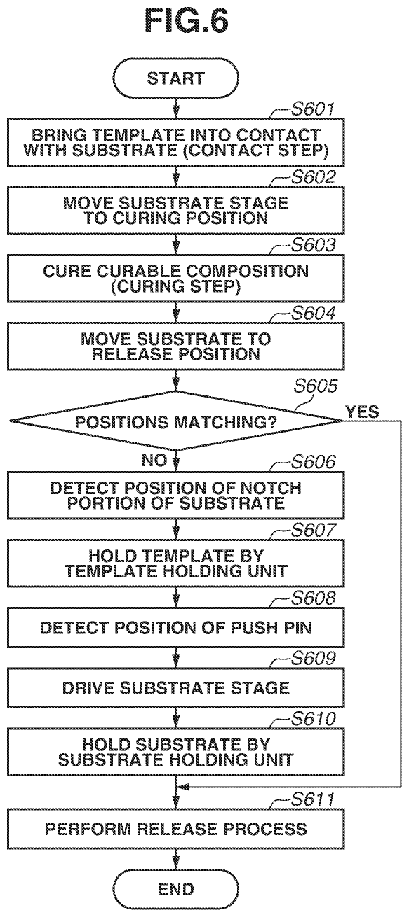

FIG. 6 is a flowchart illustrating a planarization process in the present exemplary embodiment. The control unit 200 comprehensively controls each unit of the planarization apparatus 100, so that processing represented by the flowchart in FIG. 6 is implemented. Here, processing steps after the substrate 1 is conveyed from the first processing unit 101 to the second processing unit 102 will be described.

In step S601, the control unit 200 brings the template 11 into contact with the substrate 1 onto which the curable composition is applied (the contact step). Then in step S602, the control unit 200 moves the substrate stage 4 holding the substrate 1, which is in contact with the template 11 with the curable composition interposed therebetween, to the position (the curing position) facing the exposure unit 23. In step S603, the exposure unit 23 emits light to cure the curable composition (the curing step). In step S604, the substrate stage 4 moves the substrate 1 to the release position.

In step S605, the control unit 200 determines whether the position of the push pin 14 matches the position of the notch portion of the substrate 1. Specifically, the control unit 200 determines whether the position of the push pin 14 matches the position of the notch portion based on detection using the alignment scope 22. Another optical system and another image pickup system may be used to perform the determination. Since the position of the push pin 14 may not match the position of the notch portion in step S601 to step S604, step S605 and the subsequent steps are performed after these steps, but may be performed before these steps.

If the control unit 200 determines that the position of the push pin 14 and the position of the notch portion match each other (YES in step S605), the processing proceeds to step S611. In step S611, the control unit 200 performs the release operation. If the control unit 200 determines that the position of the push pin 14 and the position of the notch portion do not match each other (NO in step S605), the processing proceeds to step S606. In step S606, the substrate stage 4 moves the substrate 1 to the detection position of the detection unit 300, and the detection unit 300 measures the position of the notch portion of the substrate 1, and subsequently, the substrate stage 4 is moved to the position facing the template holding unit 12.

In step S607, the template holding unit 12 holds the template 11, and the substrate holding unit 2 releases the substrate 1. At this time, since the state where the substrate 1 and the template 11 are in contact with each other is maintained by the curable composition cured in the curing step, the substrate 1 and the template 11 are simultaneously held by vacuum suction.

In step S608, the substrate stage 4 is moved to the detection position of the detection unit 300, the detection unit 300 measures the position of the push pin 14, and then the substrate stage 4 is moved to the position facing the template holding unit 12.

In step S609, based on the position information about the notch portion of the substrate 1 and the position information about the push pin 14 obtained by the detection unit 300, the control unit 200 drives the substrate stage 4 so that the position of the notch portion and the position of the push pin 14 match each other.

In step S610, the head drive unit 10 lowers the substrate 1 and the template 11 held by the template holding unit 12, so that the substrate holding unit 2 also holds the substrate 1 by suction.

In step S611, the control unit 200 performs the release process while the push pin 14 is assisting the release of the template 11 from the substrate 1. Specifically, the head drive unit 10 raises the template 11, so that the template 11 is separated from the curable composition cured on the substrate 1. At this time, the push pin 14 of the substrate stage 4 is caused to protrude from the opening of the notch portion of the substrate 1 and press against the template 11, thereby assisting the release.

In the technique of alignment by the detection unit 300, the center position of each of the substrate 1 and the substrate holding unit 2 on the substrate stage 4, the position of the notch portion of the substrate 1, and the position of the push pin 14 are determined by measurement. Specifically, the detection unit 300 determines the center position of each of the substrate 1 and the substrate holding unit 2 by measuring the external form of each of the substrate 1 and the substrate holding unit 2. Subsequently, the detection unit 300 measures the position of the notch portion of the substrate 1. An angle formed by a line connecting two points, i.e., the center position of the substrate 1 and the position of the notch portion of the substrate 1 that are measured beforehand, and the X-axis or the Y-axis is calculated, so that an angle component in the θZ direction is calculated. Next, the detection unit 300 measures the position of the push pin 14. An angle formed by a line connecting two points, i.e., the center position of the substrate holding unit 2 and the position of the push pin 14 that are measured beforehand, and the X-axis or the Y-axis is calculated, so that an angle component in the θZ direction is calculated. The alignment can be performed by driving the substrate stage 4 using the obtained information about the center positions and the angle components.

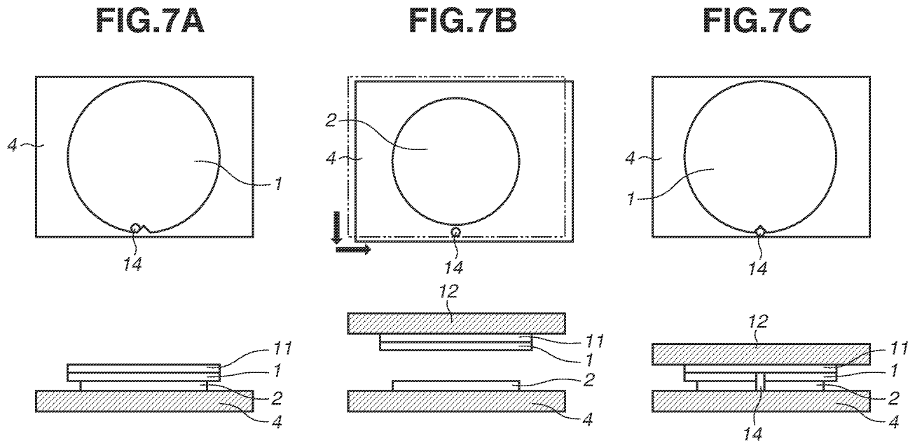

FIGS. 7A to 7C are diagrams illustrating the release process according to the first exemplary embodiment. FIG. 7A is a schematic diagram illustrating a state where the substrate 1 in contact with the template 11 with the curable composition interposed therebetween is placed on the substrate stage 4 after the contact step and the curing step.

FIG. 7B illustrates a state where the substrate 1 and the template 11 are held together by the template holding unit 12 in step S607, and the substrate stage 4 can be driven in a state of not holding the substrate 1. The alignment control in step S608 and step S609 can be performed in this state.

FIG. 7C is a schematic diagram illustrating the release process in step S611, which is being performed with the assistance by the push pin 14 in a state where the substrate 1 and the template 11 are held by the substrate holding unit 2 and the template holding unit 12, respectively.

According to the present exemplary embodiment described above, the assistance using the push pin 14 in the release process can be reliably performed, and the template 11 can be stably released from the curable composition on the substrate 1.

In a second exemplary embodiment, a description will be given of a case where the push pin 14 integrally formed on the substrate stage 4 is adjusted in a state where the template 11 and the substrate 1 are held by the substrate conveyance unit 25. The description of the same part as that of the first exemplary embodiment will be omitted, and mainly a different part will be described.

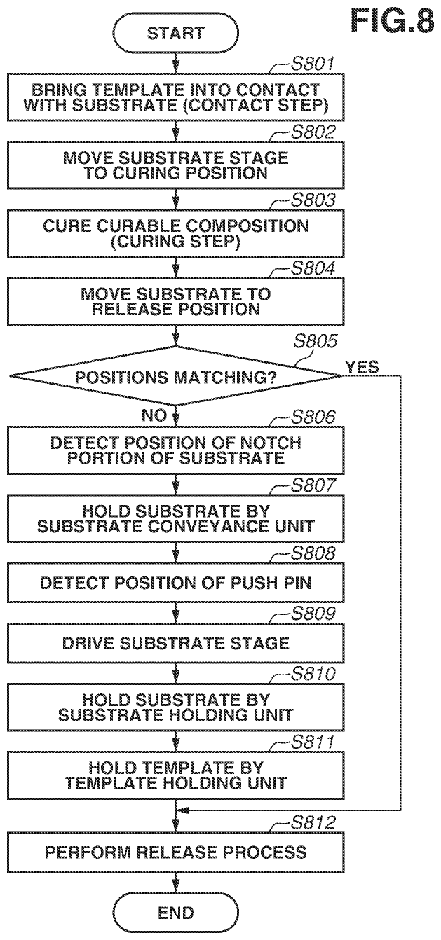

FIG. 8 is a flowchart illustrating a planarization process in the present exemplary embodiment. The control unit 200 comprehensively controls each unit of the planarization apparatus 100, so that processing represented by the flowchart in FIG. 8 is implemented. Here, processing steps after the substrate 1 is conveyed from the first processing unit 101 to the second processing unit 102 will be described.

Step S801 to step S805 are similar to step S601 to step S605 of the first exemplary embodiment and thus will not be described.

If the control unit 200 determines that the position of the push pin 14 and the position of the notch portion match each other (YES in step S805), the processing proceeds to step S812. In step S812, the control unit 200 performs the release operation. If the control unit 200 determines that the position of the push pin 14 and the position of the notch portion do not match each other (NO in step S805), the processing proceeds to step S806. In step S806, the substrate stage 4 moves the substrate 1 to the detection position of the detection unit 300, the detection unit 300 measures the position of the notch portion of the substrate 1, and then the substrate stage 4 is moved to the position facing the template holding unit 12.

In step S807, the substrate conveyance unit 25 holds the substrate 1. At this time, the state where the substrate 1 and the template 11 are in contact with each other is maintained by the curable composition cured in the curing step, and thus, the substrate 1 and the template 11 are simultaneously held.

In step S808, the substrate stage 4 is moved to the detection position of the detection unit 300, the detection unit 300 measures the position of the push pin 14, and then the substrate stage 4 is moved to the position facing the template holding unit 12.

In step S809, based on the position information about the notch portion of the substrate 1 and the position information about the push pin 14 obtained by the detection unit 300, the control unit 200 drives the substrate stage 4 so that the position of the notch portion and the position of the push pin 14 overlap each other.

In step S810, the control unit 200 causes the substrate holding unit 2 to hold the substrate 1 held by the substrate conveyance unit 25, by suction. Then in step S811, the head drive unit 10 is moved down, so that the template holding unit 12 holds the template 11.

In step S812, the control unit 200 performs the release process with the push pin 14 assisting in the release of the template 11 from the substrate 1. Specifically, the head drive unit 10 raises the template 11, so that the template 11 is separated from the curable composition cured on the substrate 1. At this time, the push pin 14 of the substrate stage 4 is caused to protrude from the opening of the notch portion of the substrate 1 and press against the template 11, thereby assisting the release.

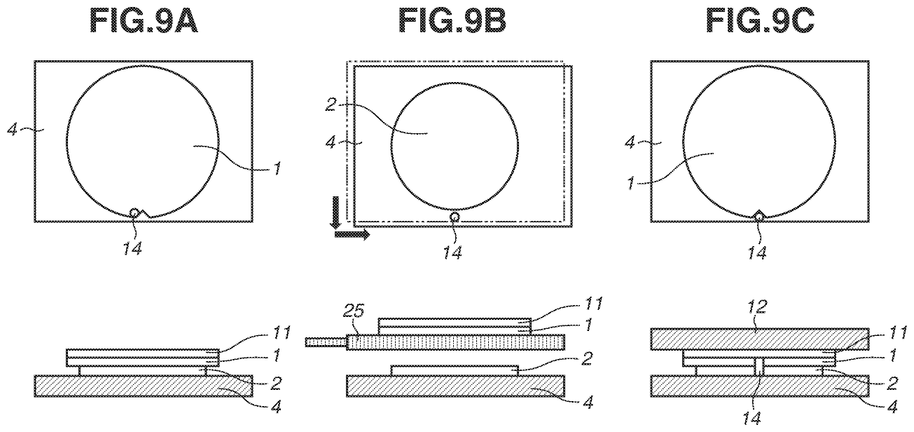

FIGS. 9A to 9C are diagrams illustrating the release process according to the second exemplary embodiment. FIG. 9A is a schematic diagram illustrating a state where the substrate 1 in contact with the template 11 with the curable composition interposed therebetween is placed on the substrate stage 4 after the contact step and the curing step.

FIG. 9B illustrates a state where the substrate 1 and the template 11 are held together by the substrate conveyance unit 25 in step S807, and the substrate stage 4 can be driven in a state of not holding the substrate 1. The alignment control in step S808 and step S809 can be performed in this state.

FIG. 9C is a schematic diagram illustrating the release process in step S812, which is being performed with the assistance by the push pin 14 in a state where the substrate 1 and the template 11 are held by the substrate holding unit 2 and the template holding unit 12, respectively.

According to the present exemplary embodiment described above, the assistance using the push pin 14 in the release process can be reliably performed, and the template 11 can be stably released from the curable composition on the substrate 1.

In a third exemplary embodiment, there will be described a case where the push pin 14 configured to be driven independently of the substrate stage 4 is adjusted. The description of the same part as those of the first exemplary embodiment and the second exemplary embodiment will be omitted, and mainly a different part will be described.

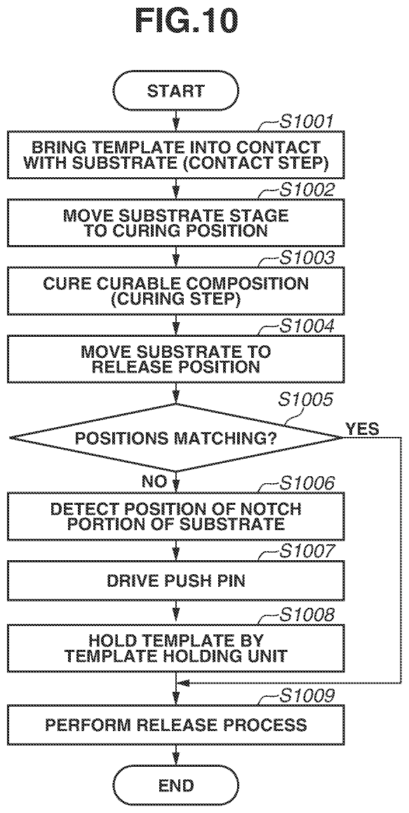

FIG. 10 is a flowchart illustrating a planarization process in the present exemplary embodiment. The control unit 200 comprehensively controls each unit of the planarization apparatus 100, so that processing represented by the flowchart in FIG. 10 is implemented. Here, processing steps after the substrate 1 is conveyed from the first processing unit 101 to the second processing unit 102 will be described.

In the present exemplary embodiment, a second drive unit (a pressing member drive unit) not illustrated is provided. The second drive unit is independent of the stage drive unit 31 for the substrate stage 4, and can drive the push pin 14 and the substrate holding unit 2 (the substrate stage) relatively. The second drive unit is controlled by the control unit 200.

Step S1001 to step S1005 are similar to step S601 to step S605 of the first exemplary embodiment and thus will not be described.

If the control unit 200 determines that the position of the push pin 14 and the position of the notch portion match each other (YES in step S1005), the processing proceeds to step S1009. In step 1009, the control unit 200 performs the release operation. If the control unit 200 determines that the position of the push pin 14 and the position of the notch portion do not match each other (NO in step S1005), the processing proceeds to step S1006. In step S1006, the substrate stage 4 moves the substrate 1 to the detection position of the detection unit 300, the detection unit 300 measures the position of the notch portion of the substrate 1, and then the substrate stage 4 is moved to the position facing the template holding unit 12.

In step S1007, based on the position information about the notch portion of the substrate 1 obtained by the measurement by the detection unit 300, the control unit 200 controls the second drive unit so that the push pin 14 is driven to overlap the position of the notch portion of the substrate 1.

In step S1008, the control unit 200 controls the head drive unit 10 to move down, so that the template holding unit 12 holds the template 11.

In step S1009, the control unit 200 performs the release process with the assistance by the push pin 14 in the release of the template 11 from the substrate 1. Specifically, the head drive unit 10 raises the template 11, so that the template 11 is separated from the curable composition cured on the substrate 1. At this time, the push pin 14 provided on the substrate stage 4 is caused to protrude from the opening of the notch portion of the substrate 1 and press against the template 11, thereby assisting the release.

In the technique of alignment by the detection unit 300, the center position of the substrate 1 and the position of the notch portion of the substrate 1 are determined by measurement. Specifically, the detection unit 300 determines the center position of the substrate 1 by measuring the external form of the substrate 1. Subsequently, the detection unit 300 measures the position of the notch portion of the substrate 1. An angle formed by a line connecting two points, i.e., the center position of the substrate 1 and the position of the notch portion of the substrate 1 that are measured beforehand, and the X-axis or the Y-axis is calculated, so that an angle component in the θZ direction is calculated. Using the obtained information about the center position and the angle component, the coordinates of the position of the notch portion of the substrate 1 are determined, and the control unit 200 controls the second drive unit so that the push pin 14 is driven to be located at the coordinates of the notch portion of the substrate 1.

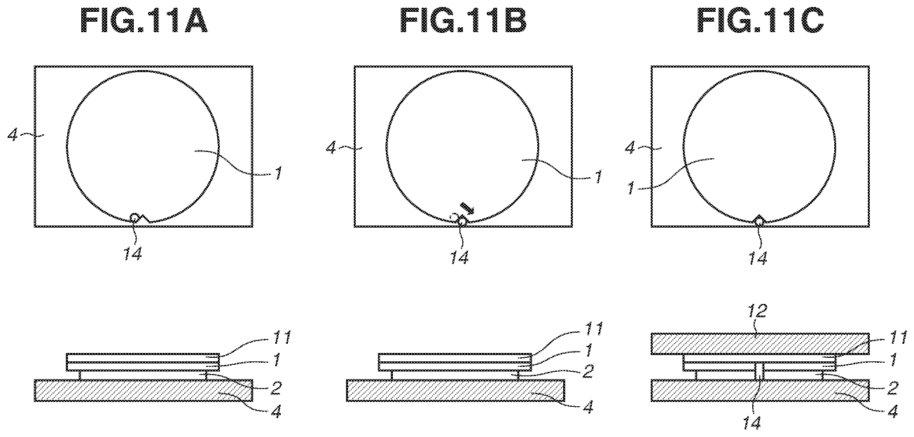

FIGS. 11A to 11C are diagrams illustrating the release process according to the third exemplary embodiment. FIG. 11A is a schematic diagram illustrating a state where the substrate 1 in contact with the template 11 with the curable composition interposed therebetween is placed on the substrate stage 4 after the contact step and the curing step.

FIG. 11B illustrates a state where the alignment is performed with the substrate 1 and the template 11 being held together by the substrate holding unit 2 in step S1007.

FIG. 11C is a schematic diagram illustrating the release process in step S1009, which is being performed with the assistance by the push pin 14 in a state where the substrate 1 and the template 11 are held by the substrate holding unit 2 and the template holding unit 12, respectively.

According to the present exemplary embodiment described above, the assistance using the push pin 14 in the release process can be reliably performed, and the template 11 can be stably released from the curable composition on the substrate 1.

The exemplary embodiments of the present disclosure are described above, but the present disclosure is not limited to these exemplary embodiments, and can be modified and changed in various manners within the scope of the spirit thereof. For example, the push pin 14 is used as a means to assist the release step, but may be any other means as long as it can supply a force that acts in the release direction. Specific examples of such an alternative means include a means using air pressure. Further, the example in which the assisting means for the release step is provided on the substrate stage 4 is described, but the assisting means may be provided on the substrate holding unit 2.

Next, a description will be given of a method of manufacturing an article (e.g., a semiconductor integrated circuit (IC) element, a liquid crystal display element, a color filter, or a Micro-Electro Mechanical System (MEMS)) using the above-described planarization apparatus or planarization method. This manufacturing method includes steps of planarizing a composition placed on a substrate (such as a wafer or a glass substrate) in a state where the composition is in contact with a mold and separating the composition from the mold, using the above-described planarization apparatus. By further performing a step of processing the substrate having the planarized composition to form a pattern thereon using a lithography apparatus, and a step of performing other known processes on the processed substrate, an article is manufactured. The other processes include etching, resist removing, dicing, bonding, and packaging. According to the present manufacturing method, high-quality articles can be manufactured compared to those manufactured by the conventional methods.

While the present disclosure has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2020-205114, filed Dec. 10, 2020, which is hereby incorporated by reference herein in its entirety.

What is claimed is:

1. A planarization apparatus that planarizes a composition on a substrate using a mold, the planarization apparatus comprising:
a substrate holding unit configured to hold the substrate;
a mold holding unit configured to hold the mold;
a drive unit configured to drive the substrate holding unit and the mold holding unit;
a pressing member configured to press a part of the mold which is in contact with the substrate with a composition interposed therebetween to separate the substrate from the mold; and
a control unit configured to control a position of the pressing member to a predetermined position.

2. The planarization apparatus according to claim 1, wherein the control unit causes the pressing member to press the part of the mold in a state where the position of the pressing member is adjusted to the predetermined position.

3. The planarization apparatus according to claim 1, wherein the control unit adjusts the position of the pressing member to the predetermined position by moving the position of the pressing member, in a state where the substrate is not held by the substrate holding unit.

4. The planarization apparatus according to claim 1, further comprising a detection unit configured to detect a position of a notch portion of the substrate,
wherein the control unit controls the position of the notch portion and the position of the pressing member to match each other by causing the detection unit to detect the position of the notch portion, in a state where the composition on the substrate and the mold are in contact with each other.

5. The planarization apparatus according to claim 1,
wherein the pressing member is a part of the substrate holding unit, and
wherein the control unit adjusts the position of the pressing member to the predetermined position by causing the drive unit to move the substrate holding unit.

6. The planarization apparatus according to claim 5, wherein the control unit causes the drive unit to move the substrate holding unit in a state where the substrate and the mold in contact with each other with the composition interposed therebetween are held by the mold holding unit.

7. The planarization apparatus according to claim 5, wherein the control unit caused the drive unit to move the substrate holding unit, in a state where the substrate and the mold in contact with each other with the composition interposed therebetween are held by a substrate conveyance unit.

8. The planarization apparatus according to claim 1, further comprising a pressing member drive unit configured to drive the pressing member,
wherein the control unit adjusts the position of the pressing member to the predetermined position by moving the pressing member drive unit.

9. The planarization apparatus according to claim 1, further comprising a curing unit configured to cure the composition,
wherein the control unit adjusts the position of the pressing member to the predetermined position after the curing unit cures the composition in a state where the composition on the substrate and the mold are in contact with each other.

10. A planarization method of planarizing a composition on a substrate using a mold, the planarization method comprising:
bringing the mold into contact with the composition on the substrate;
adjusting a position of a pressing member to a predetermined position; and
pressing a part of the mold from the substrate side using the pressing member to separate the substrate from the mold, in a state where the position of the pressing member is the predetermined position.

11. An article manufacturing method of manufacturing an article using a processed substrate, the article manufacturing method comprising:
planarizing a composition on a substrate using a planarization apparatus that planarizes a composition on a substrate using a mold, the planarization apparatus including:
a substrate holding unit configured to hold the substrate;
a mold holding unit configured to hold the mold;
a drive unit configured to drive the substrate holding unit and the mold holding unit;
a pressing member configured to press a part of the mold which is in contact with the substrate with a composition interposed therebetween to separate the substrate from the mold; and
a control unit configured to control a position of the pressing member to a predetermined position; and
processing the substrate having the planarized composition.
